(19) United States
(12) Patent Application Publication
(10) Pub. No.: US 2021/0288056 A1
(43) Pub. Date: Sep. 16, 2021

(54) SEMICONDUCTOR DEVICE AND MANUFACTURING METHOD THEREOF

(71) Applicant: Kioxia Corporation, Minato-ku (JP)

(72) Inventors: Takayuki ITO, Yokkaichi (JP); Tomonari SHIODA, Yokkaichi (JP)

(73) Assignee: Kioxia Corporation, Minato-ku (JP)

(21) Appl. No.: 17/009,144

(22) Filed: Sep. 1, 2020

(30) Foreign Application Priority Data
Mar. 11, 2020 (JP) 2020-042305

(51) Int. Cl. H01L 27/11524; H01L 23/522; H01L 27/1157

(52) U.S. Cl. CPC H01L 27/11524; H01L 27/1157; H01L 23/5226

(57) ABSTRACT

A semiconductor device according to one embodiment includes a semiconductor substrate, first transistors including a first diffusion layer provided on a surface of the semiconductor substrate and including impurities and carbon, and first contact plugs provided on the first diffusion layer. The first diffusion layer includes a first region being in contact with the first contact plugs and a second region covering the first region. A concentration of the carbon is higher than that of the impurities in the first region as a depth from the surface is larger.

### CROSS-REFERENCE TO RELATED APPLICATIONS

This application is based upon and claims the benefit of priority from Japanese Patent Application No. 2020-042305, filed on Mar. 11, 2020; the entire contents of which are incorporated herein by reference.

### FIELD

The embodiments of the present invention relate to a semiconductor device and a manufacturing method thereof.

### BACKGROUND

There have been developed NAND flash memories that have a three-dimensional memory cell array configured by three-dimensionally arraying memory cells. In such a semiconductor device, there is known a structure in which a CMOS (Complementary Metal Oxide Semiconductor) circuit controlling the memory cell array is placed below the memory cells.

### BRIEF DESCRIPTION OF THE DRAWINGS

FIG. 1 is a sectional view illustrating a structure of a semiconductor device according to one embodiment;

FIG. 2 is a sectional view enlargedly illustrating a part of a CMOS circuit;

FIG. 3 is a graph illustrating concentration profiles of impurities and carbon in a source layer and a drain layer;

FIG. 4 is a sectional view illustrating an internal structure of a stacked body;

FIG. 5 is a sectional view illustrating a process of forming a transistor on a surface of a semiconductor substrate;

FIG. 6 is a sectional view illustrating a process of forming an interlayer dielectric film on a semiconductor substrate;

FIG. 7 is a sectional view illustrating a process of forming contact holes in the interlayer dielectric film;

FIG. 8 is a sectional view illustrating a process of forming an epitaxial layer in the contact holes;

FIG. 9 is a sectional view illustrating a process of forming a transistor on a surface of a semiconductor substrate;

FIG. 10 is a sectional view illustrating a process of forming an interlayer dielectric film on a semiconductor substrate;

FIG. 11 is a sectional view illustrating a process of forming the contact holes;

FIG. 12 is a sectional view illustrating a process of forming an epitaxial layer in the contact holes;

FIG. 13 is a sectional view illustrating a process of forming other contact holes;

FIG. 14 is a sectional view illustrating a process of forming contact plugs; and

FIG. 15 is a graph illustrating a relation between a variation amount of wafer warp and a location deviation amount of a wafer pattern.

### DETAILED DESCRIPTION

Embodiments will now be explained with reference to the accompanying drawings. The present invention is not limited to the embodiments.

A semiconductor device according to one embodiment includes a semiconductor substrate, first transistors including a first diffusion layer provided on a surface of the semiconductor substrate and including impurities and carbon, and first contact plugs provided on the first diffusion layer. The first diffusion layer includes a first region being in contact with the first contact plugs and a second region covering the first region. A concentration of the carbon is higher than that of the impurities in the first region as a depth from the surface is larger.

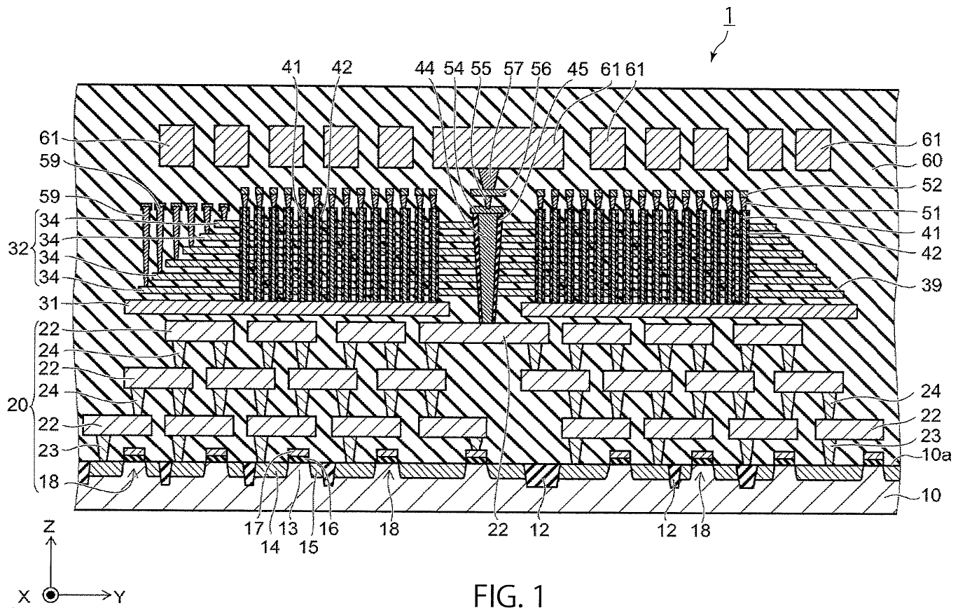

FIG. 1 is a sectional view illustrating a structure of a semiconductor device according to one embodiment. A semiconductor device 1 according to the present embodiment is a NAND non-volatile semiconductor storage device having memory cells with a three-dimensional structure, which can electrically freely erase and write data and can retain stored contents even when the power is turned off.

The semiconductor device 1 illustrated in FIG. 1 includes a semiconductor substrate 10, a peripheral circuit 20, and a stacked body 32. In the following explanations, two directions being parallel to a top surface 10a of the semiconductor substrate 10 and being orthogonal to each other are assumed as an X direction and a Y direction. A direction perpendicular to the top surface 10a and orthogonal to the X direction and the Y direction is assumed as a Z direction. The Z direction is also a stacking direction of the stacked body 32.

The semiconductor substrate 10 is, for example, a silicon substrate. STIs (Shallow Trench Isolations) 12 are selectively provided on a top layer part of the semiconductor substrate 10. The top layer part of the semiconductor substrate 10 is partitioned by the STIs 12 into a plurality of semiconductor regions 13. A source layer 14 and a drain layer 15 are formed in at least some of the semiconductor regions 13. The source layer 14 and the drain layer 15 are examples of a diffusion layer.

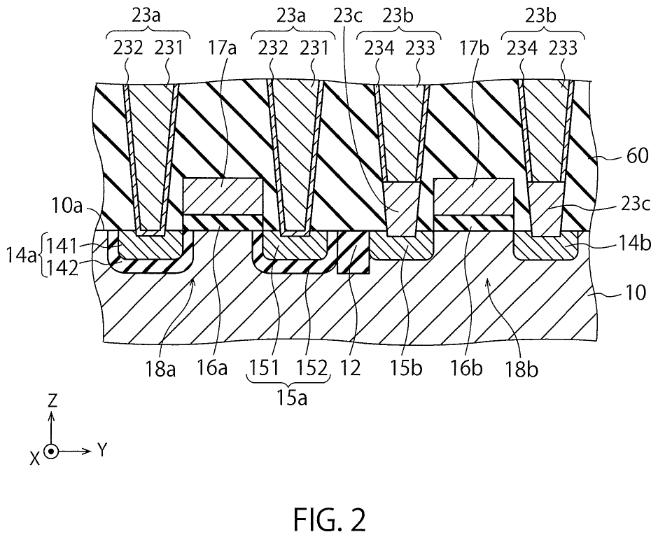

A gate dielectric film 16 and a gate electrode 17 are provided in the semiconductor regions 13. The gate dielectric film 16, the gate electrode 17, the source layer 14, and the drain layer 15 constitute a transistor 18. There are two types of transistors including a P-MOSFET (Metal Oxide Semiconductor Field Effect Transistor) and an N-MOSFET having different conductivity types as the transistors 18. The P-MOSFET and the N-MOSFET constitute a CMOS circuit. A structure of the CMOS circuit is explained below with reference to FIG. 2.

FIG. 2 is a sectional view enlargedly illustrating a part of the CMOS circuit. The CMOS circuit illustrated in FIG. 2 includes a first transistor 18a and a second transistor 18b. The first transistor 18a and the second transistor 18b are separated by the STI 12. The first transistor 18a and the second transistor 18b are illustrated as the transistors 18 in FIG. 1.

The first transistor 18a is an N-MOSFET and includes a source layer 14a, a drain layer 15a, a gate dielectric film 16a, and a gate electrode 17a. The source layer 14a, the drain layer 15a, the gate dielectric film 16a, and the gate electrode 17a are illustrated as the source layer 14, the drain layer 15, the gate dielectric film 16, and the gate electrode 17 in FIG. 1.

The source layer 14a and the drain layer 15a are examples of a first diffusion layer provided on the top surface 10a of the semiconductor substrate 10. The gate dielectric film 16a is provided on the semiconductor substrate 10 between the source layer 14a and the drain layer 15a. The gate electrode 17a is provided on the gate dielectric film 16a.

The source layer 14a includes a first region 141 and a second region 142 and the drain layer 15a includes a first region 151 and a second region 152. The first region 141 and the first region 151 include impurities and carbon (C). The impurities are, for example, arsenic (As) or phosphorus (P).

The second region 142 covers the first region 141. The second region 152 covers the first region 151. The second region 142 and the second region 152 include carbon.

The first region 141 and the first region 151 are in contact with different contact plugs 23a, respectively. The contact plugs 23a are an example of first contact plugs and are formed in an interlayer dielectric film 60. The interlayer dielectric film 60 includes silicon oxide (Si₂O₃).

Each of the contact plugs 23a includes a metallic film 231 and a barrier metal film 232. The metallic film 231 includes, for example, tungsten (W). The barrier metal film 232 includes, for example, titanium nitride (TiN) and covers the side and bottom surfaces of the metallic film 231.

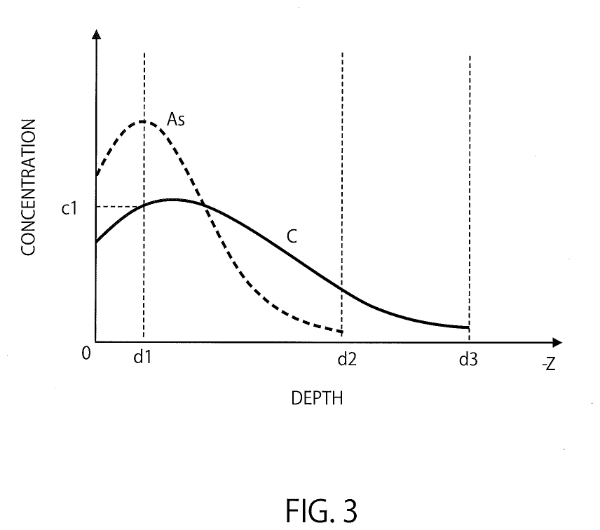

FIG. 3 is a graph illustrating concentration profiles of the impurities and carbon in the source layer 14a and the drain layer 15a. In FIG. 3, the horizontal axis represents a depth in the −Z direction from the top surface 10a of the semiconductor substrate 10 and the vertical axis represents a concentration. The solid line indicates a concentration of carbon and the dashed line indicates a concentration of arsenic.

The first region 141 and the first region 151 are in contact with bottom parts of the contact plugs 23a at a location of a depth d1 illustrated in FIG. 3. A range from the depth d1 to a depth d2 corresponds to the first region 141 and the first region 151. A range from the depth d2 to a depth d3 corresponds to the second region 142 and the second region 152.

A concentration c1 of carbon at the location of the depth d1 is equal to or higher than 1×10¹⁹ cm⁻³ and is lower than the concentration of arsenic. It was experimentally confirmed that progression of crystal defects of silicon included in the semiconductor substrate 10 was suppressed by setting the concentration c1 of carbon to be equal to or higher than 1×10¹⁹ cm⁻³. The N-type conductivity of the first region 141 and the first region 151 can be ensured by setting the concentration c1 of carbon to be lower than that of arsenic.

In the range from the depth d1 to the depth d2, that is, in the first region 141 and the first region 151, the concentration of carbon becomes higher than the concentration of arsenic as the depth from the top surface 10a is larger. Specifically, while the concentration of arsenic is higher than that of carbon at the depth d1, the relation in the level between the concentration of arsenic and the concentration of carbon is reversed at a depth on the way to the depth d2.

Referring back to FIG. 2, the second transistor 18b is a P-MOSFET and includes a source layer 14b, a drain layer 15b, a gate dielectric film 16b, and a gate electrode 17b. The source layer 14b, the drain layer 15b, the gate dielectric film 16b, and the gate electrode 17b are also illustrated as the source layer 14, the drain layer 15, the gate dielectric film 16, and the gate electrode 17 in FIG. 1.

The source layer 14b and the drain layer 15b are examples of a second diffusion layer provided on the top surface 10a of the semiconductor substrate 10. The gate dielectric film 16b is provided on the semiconductor substrate 10 between the source layer 14b and the drain layer 15b. The gate electrode 17b is provided on the gate dielectric film 16b.

The source layer 14b and the drain layer 15b include impurities. The impurities are, for example, boron (B). An epitaxial layer 23c is provided on the source layer 14b and the drain layer 15b.

While including boron in the present embodiment, the epitaxial layers 23c do not necessarily include boron.

Contact plugs 23b are provided on the epitaxial layer 23c. The contact plugs 23b are an example of second contact plugs and are formed in the interlayer dielectric film 60 similarly to the contact plug 23a.

Each of the contact plugs 23b includes a metallic film 233 and a barrier metal film 234. The metallic film 233 includes, for example, tungsten. The barrier metal film 234 includes, for example, titanium nitride and covers the side and bottom surfaces of the metallic film 233.

The contact plugs 23a and the contact plugs 23b are illustrated as the contact plugs 23 in FIG. 1. As illustrated in FIG. 1, the contact plugs 23 are connected to vias 24 with wires 22 in the bottommost layer. The peripheral circuit 20 is formed by the transistors 18, the wires 22, the contact plugs 23, and the vias 24. The peripheral circuit 20 is, for example, a sense amplifier. Plural layers of the wires 22 are provided in the interlayer dielectric film 60.

An embedded source line 31 is provided on the wire 22 in the topmost layer. A voltage is supplied from the peripheral circuit 20 to portions of the embedded source line 31. The stacked body 32 is provided on the embedded source line 31.

Channels 41 extend in the stacked body 32 in the Z direction. The channels 41 include, for example, polysilicon and have the shape of a cylinder including a closed bottom end portion. The channels 41 are connected to bit lines 52 extending in the X direction with plugs 51.

A through-via 44 extending in the Z direction is provided in the stacked body 32. The bottom end of the through-via 44 is connected to the wire 22 in the topmost layer in the peripheral circuit 20. The through-via 44 is insulated by an insulating film 45 from electrode films 34.

An intermediate wire 54, a plug 55, an intermediate wire 56, and a contact plug 57 are provided above the through-via 44. An upper layer wire 61 is provided on the contact plug 57. The through-via 44 is connected to the upper layer wire 61 with the intermediate wire 54, the plug 55, the intermediate wire 56, and the contact plug 57. A power-supply potential or a signal potential is applied to the peripheral circuit 20 through the upper layer wire 61 and the through-via 44.

The embedded source line 31, the stacked body 32, the plugs 51, the bit lines 52, the intermediate wire 54, the plug 55, the intermediate wire 56, the contact plug 57, contact plugs 59, and the upper layer wire 61 are embedded in the interlayer dielectric film 60.

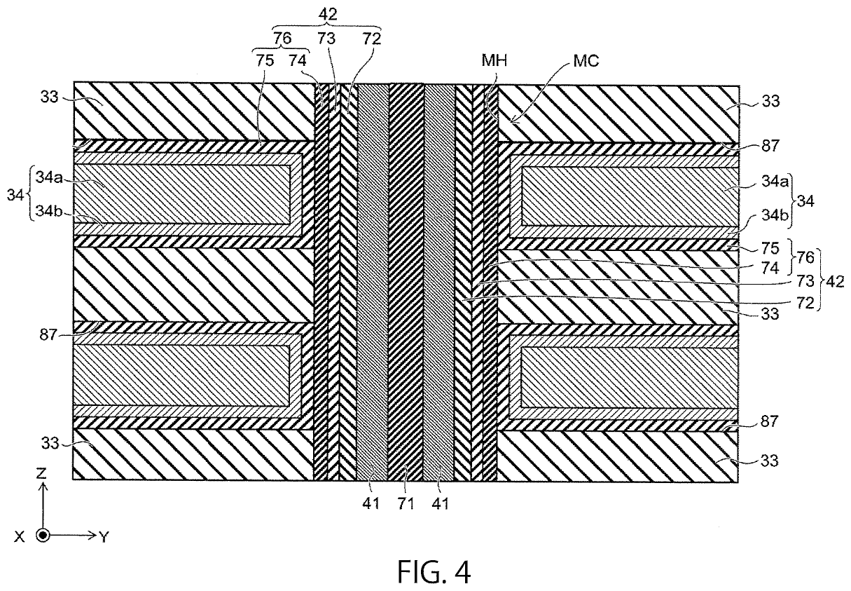

FIG. 4 is a sectional view illustrating an internal structure of the stacked body 32. A plurality of insulating films 33 and a plurality of electrode films 34 are alternately stacked on the stacked body 32 along the Z direction. The insulating films 33 include, for example, silicon oxide. Each of the electrode films 34 includes a body portion 34a including, for example, tungsten and a barrier metal layer 34b including, for example, titanium nitride. The barrier metal layer 34b covers the top and bottom surfaces of the body portion 34a and side surfaces thereof facing the channels 41. Some of the electrode films 34 function as word lines.

A memory film 42 is provided between the electrode films 43 and the channels 41. A core member 71 including, for example, silicon oxide is provided in the cylindrical channels 41. The memory film 42 is formed of a tunnel dielectric film 72, a charge accumulation film 73, and a block dielectric film 76. Intersections between the electrode films 34 functioning as the word lines and the memory film 42 are memory cells. A plurality of memory cells are connected in series in the Z direction to form a memory cell array in the stacked body 32.

The tunnel dielectric film 72 is located on the side surfaces of the channels 41. The tunnel dielectric film 72 includes, for example, silicon oxide. The cylindrical charge accumulation film 73 is located on the side surface of the tunnel dielectric film 72. The charge accumulation film 73 includes, for example, silicon nitride. A low-permittivity layer 74 is provided on the side surface of the charge accumulation film 73. The low-permittivity layer 74 includes, for example, silicon oxide.

A high-permittivity layer 75 is provided on the top and bottom surfaces of the electrode films 34 and the side surfaces thereof facing the channels 41. The high-permittivity layer 75 includes a material having a relative permittivity higher than that of silicon oxide, for example, aluminum oxide (Al₂O₃). The block dielectric film 76 is composed of the low-permittivity layer 74 and the high-permittivity layer 75.

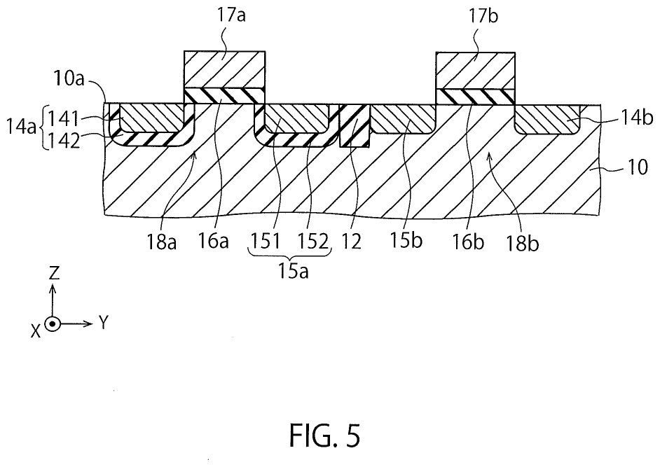

A manufacturing method of the semiconductor device according to the present embodiment is explained below with reference to FIGS. 5 to 8. A manufacturing process of the CMOS circuit illustrated in FIG. 2 is explained here.

First, the first transistors 18a and the second transistors 18b are formed on the semiconductor substrate 10 as illustrated in FIG. 5. The gate dielectric films 16a and the gate dielectric films 16b in the first transistors 18a and the second transistors 18b can be formed, for example, by oxidizing silicon included in the semiconductor substrate 10. The gate electrodes 17a and the gate electrodes 17b can be formed of, for example, polysilicon.

The source layers 14a and the drain layers 15a of the first transistors 18a can be formed by implanting carbon and impurities including arsenic or phosphorus in the top surface 10a of the semiconductor substrate 10 and diffusing the carbon and the impurities thereto. While carbon is first implanted and then the impurities are implanted in the present embodiment, the impurities may be implanted prior to carbon. Meanwhile, the source layers 14b and the drain layers 15b of the second transistors 18b can be formed by implanting impurities such as boron and diffusing the impurities.

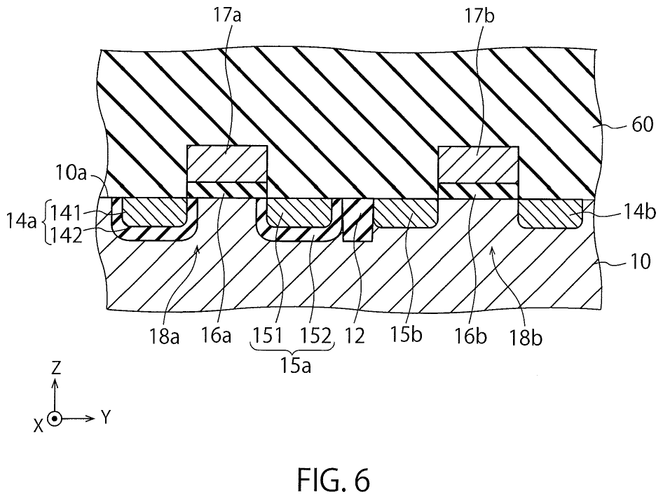

Next, the interlayer dielectric film 60 is formed on the semiconductor substrate 10 as illustrated in FIG. 6. Accordingly, the first transistors 18a and the second transistors 18b are covered by the interlayer dielectric film 60.

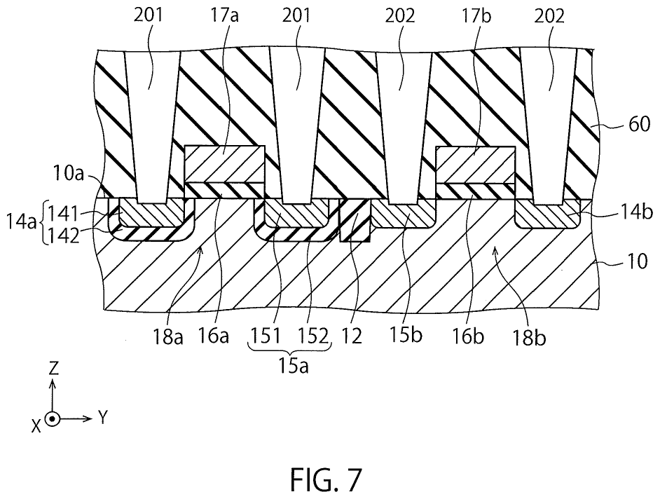

Subsequently, contact holes 201 and contact holes 202 penetrating through the interlayer dielectric film 60 in the Z direction are simultaneously formed as illustrated in FIG. 7. The contact holes 201 and the contact holes 202 are examples of first contact holes and second contact holes, respectively, and can be formed by RIE (Reactive Ion Etching). The source layers 14a and the drain layers 15a are exposed through the contact holes 201. The source layers 14b and the drain layers 15b are exposed through the contact holes 202.

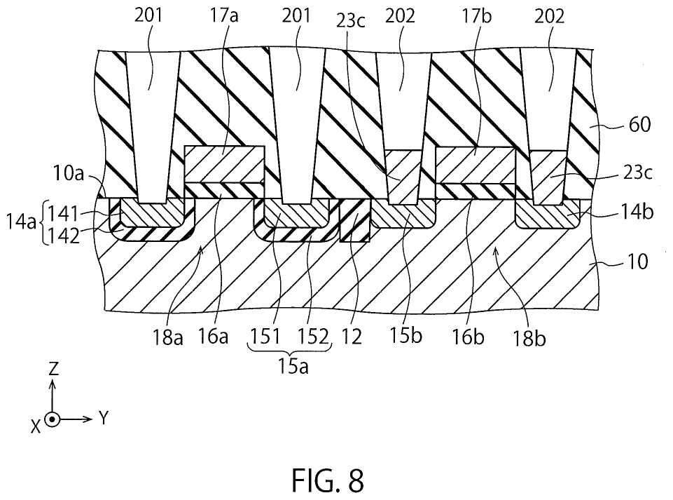

Next, the epitaxial layer 23c is formed in the contact holes 202 as illustrated in FIG. 8. The epitaxial layer 23c can be formed by epitaxially growing silicon included in the source layers 14b and the drain layers 15b. At this time, the source layers 14a and the drain layers 15a of the first transistors 18a have carbon included therein. Therefore, the incubation time of epitaxial growth of the source layers 14a and the drain layers 15a is long. Accordingly, the N-type conductivity of the source layers 14a and the drain layers 15a is maintained and the epitaxial layer 23c can be formed only in the second transistors 18b.

Finally, at the same time as the contact plugs 23a are respectively formed in the contact holes 201, the contact plugs 23b are respectively formed in the contact holes 202 as illustrated in FIG. 2. Specifically, the barrier metal film 232 is first formed on the inner surfaces of the contact holes 201 by CVD (Chemical Vapor Deposition) or ALD (Atomic Layer Deposition). At the same time, the barrier metal film 234 is formed on the inner surfaces of the contact holes 202. Subsequently, a metal such as tungsten is embedded in the contact holes 201 and the contact holes 202, whereby the metallic film 231 and the metallic film 233 are simultaneously formed.

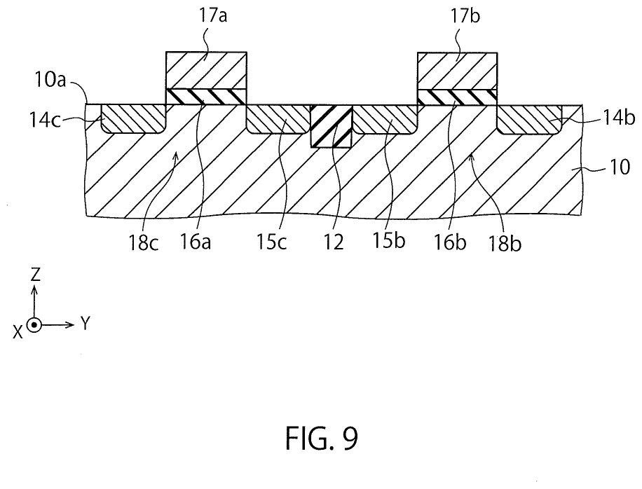

A manufacturing method of a CMOS circuit according to a comparative example is explained below with reference to FIGS. 9 to 14.

First, transistors 18c and the second transistors 18b are formed on the semiconductor substrate 10 as illustrated in FIG. 9. Source layers 14c and drain layers 15c of the transistors 18c include impurities such as arsenic or phosphorus and do not include carbon.

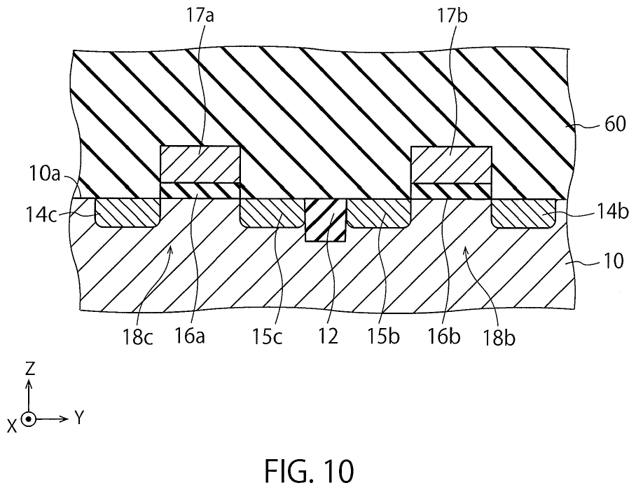

Next, the interlayer dielectric film 60 is formed on the semiconductor substrate 10 as illustrated in FIG. 10.

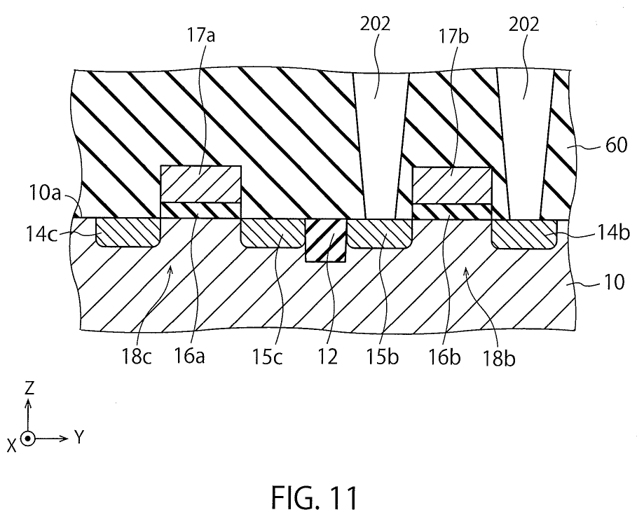

Subsequently, the contact holes 202 are formed as illustrated in FIG. 11.

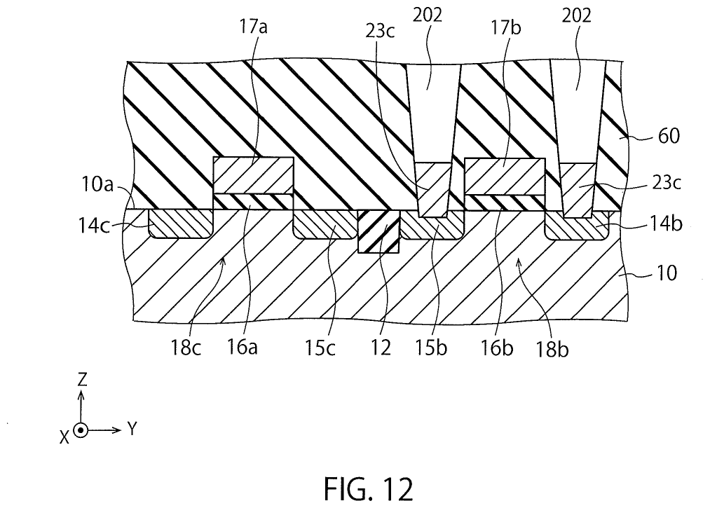

Next, the epitaxial layer 23c is formed in the contact holes 202 as illustrated in FIG. 12.

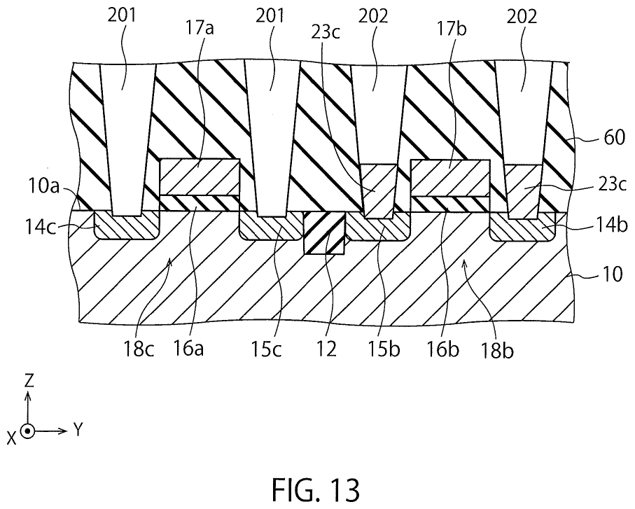

Next, the contact holes 201 are formed as illustrated in FIG. 13.

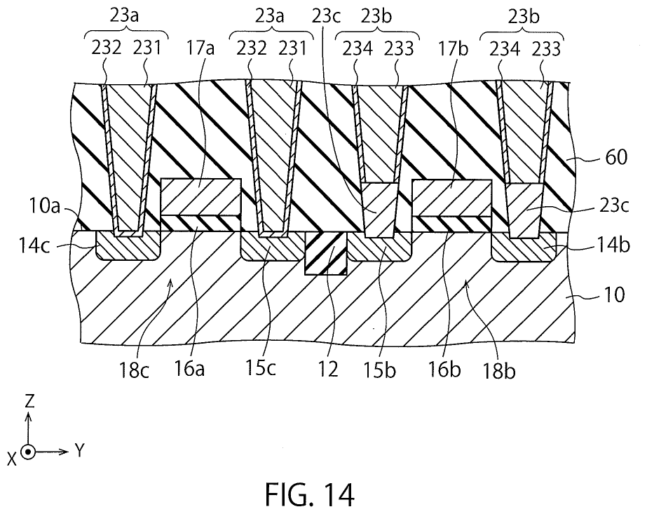

Finally, at the same time as the contact plugs 23a are respectively formed in the contact holes 201, the contact plugs 23b are respectively formed in the contact holes 202 as illustrated in FIG. 14.

In the CMOS circuit according to the comparative example described above, the source layers 14c and the drain layers 15c of the transistors 18c do not include carbon. Therefore, the contact holes 201 need to be formed at a different step from the step of forming the contact holes 202 to prevent the epitaxial layer 23c from being formed on the source layers 14c and the drain layers 15c.

In contrast, the source layers 14a and the drain layers 15a of the first transistors 18a include carbon in the present embodiment. Therefore, formation of the epitaxial layer 23c on the source layers 14a and the drain layers 15a can be avoided. This enables the contact holes 201 and the contact holes 202 to be formed at the same time. As a result, the manufacturing time of contacts is shortened and the manufacturing cost can be accordingly reduced.

In a case in which arsenic is included as the impurities in the source layers 14c and the drain layers 15c, the atomic radius of arsenic is larger than that of silicon. Therefore, crystal defects are likely to be generated in the source layers 14c and the drain layers 15c and characteristic detects such as increase in the leakage current may occur.

In contrast, carbon is included in the source layers 14a and the drain layers 15a of the first transistors 18a in the present embodiment. The atomic radius of carbon is smaller than that of arsenic. Therefore, carbon binds to silicon and suppresses progression of crystal defects. An element that can suppress progression of crystal defects, such as nitrogen may be included instead of carbon in the source layers 14a and the drain layers 15a.

After the CMOS circuit is formed in the manner described above, the stacked body 32, the memory film 42, and the like are formed on the contact plugs 23. Because the stacked body 32 and the memory film 42 are formed by a commonly used method, detailed explanations thereof are omitted. Because the stacked body 32 and the memory film 42 are formed in a high-temperature condition in the common method, the CMOS circuit is also heated.

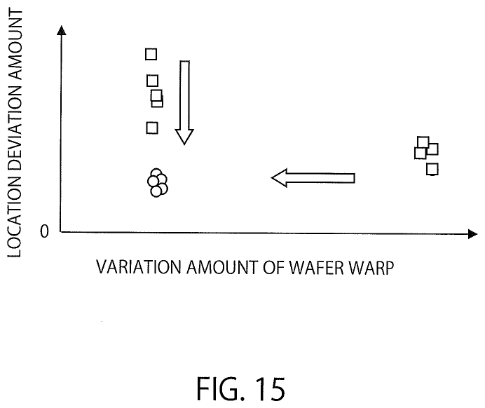

FIG. 15 is a graph illustrating a relation between a variation amount of wafer warp and a location deviation amount of a wafer pattern. In FIG. 15, the horizontal axis represents a variation amount of wafer warp between before and after heat treatment and the vertical axis represents a location deviation amount of a wafer pattern formed by a lithography technology. Squares in FIG. 15 indicate characteristics of a wafer on which the transistors 18c according to the comparative example are provided. Meanwhile, circles in FIG. 15 indicate characteristics of a wafer on which the first transistors 18a according to the present embodiment are provided.

With the transistors 18c, the variation amount of wafer warp between before and after heat treatment to form the stacked body 32 or the memory film 42 is sometimes large if crystal defects occur on the source layer 14c and the drain layer 15c. The location deviation amount of a wafer pattern formed by the lithography technology is also sometimes large.

On the other hand, progression of crystal defects in the source layer 14a and the drain layer 15a is suppressed in the present embodiment. Accordingly, the variation amount of wafer warp and the location deviation amount of the wafer pattern can be reduced as illustrated in FIG. 15. As a result, the manufacturing yield can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor substrate;
first transistors comprising a first diffusion layer provided on a surface of the semiconductor substrate and including impurities and carbon; and
first contact plugs provided on the first diffusion layer, wherein
the first diffusion layer comprises a first region being in contact with the first contact plugs, and a second region covering the first region, and
a concentration of the carbon is higher than that of the impurities in the first region as a depth from the surface is larger.

2. The device of claim 1, wherein the concentration of the carbon is equal to or higher than 1×10¹⁹ cm⁻³ and is lower than the concentration of the impurities in a contact portion between bottoms of the first contact plugs and the first region.

3. The device of claim 1, further comprising:
second transistors comprising a second diffusion layer provided on the surface of the semiconductor substrate and having a conductivity type different from that of the first diffusion layer;
an epitaxial layer provided on the second diffusion layer; and
second contact plugs provided on the epitaxial layer.

4. The device of claim 3, further comprising:
a stacked body placed on the first contact plugs and the second contact plugs and having electrode films and insulating films alternately stacked thereon; and
memory films provided in the stacked body.

5. The device of claim 1, wherein the impurities are arsenic (As) or phosphorus (P).

6. The device of claim 1, wherein a level relation between the concentration of the impurities and the concentration of the carbon is reversed in the first region.

7. The device of claim 1, wherein the concentration of the carbon is higher than that of the impurities in the second region.

8. A manufacturing method of a semiconductor device, the method comprising:
forming first transistors by forming a first diffusion layer including impurities and carbon on a surface of a semiconductor substrate; and
forming first contact plugs on the first diffusion layer, wherein
the carbon and the impurities are implanted to the surface at a different timing to be diffused to the surface, thereby forming a first region in which a concentration of the carbon is higher than that of the impurities as a depth from the surface is larger, and a second region covering the first region in the first diffusion layer.

9. The method of claim 8, comprising:
forming second transistors by forming a second diffusion layer having a conductivity type different from that of the first diffusion layer on the surface of the semiconductor substrate;
forming an interlayer dielectric film on the first transistors and on the second transistors;
simultaneously forming first contact holes exposing the first diffusion layer and second contact holes exposing the second diffusion layer in the interlayer dielectric film;
forming an epitaxial layer in the second contact holes;
forming the first contact plugs in the first contact holes, respectively; and
forming second contact plugs on the epitaxial layer in the second contact holes at a same time as the first contact plugs are formed.

10. The method of claim 8, wherein the concentration of the carbon is equal to or higher than 1×10¹⁹ cm⁻³ and is lower than the concentration of the impurities in a contact portion between bottoms of the first contact plugs and the first region.

11. The method of claim 9, comprising:
forming a stacked body placed on the first contact plugs and the second contact plugs and having electrode films and insulating films alternately stacked thereon; and
forming memory films in the stacked body.

12. The method of claim 8, wherein the impurities are arsenic (As) or phosphorus (P).

13. The method of claim 8, wherein a level relation between the concentration of the impurities and the concentration of the carbon is reversed in the first region.

14. The method of claim 8, wherein the concentration of the carbon is higher than that of the impurities in the second region.
